(19) United States
(12) Patent Application Publication
(10) Pub. No.: US 2016/0160089 A1
(43) Pub. Date: Jun. 9, 2016

(54) PRESSURE-SENSITIVE ADHESIVE SHEET TO BE USED IN PRODUCTION OF SEMICONDUCTOR

(71) Applicant: NITTO DENKO CORPORATION, Osaka (JP)

(72) Inventors: Shunpei TANAKA, Osaka (JP); Tomokazu TAKAHASHI, Osaka (JP); Jun AKIYAMA, Osaka (JP)

(73) Assignee: NITTO DENKO CORPORATION, Osaka (JP)

(21) Appl. No.: 14/951,591

(22) Filed: Nov. 25, 2015

(30) Foreign Application Priority Data
Dec. 9, 2014 (JP) 2014-248989

(51) Int. Cl. C09J 7/02; H01L 21/683

(52) U.S. Cl. CPC C09J 7/0246; H01L 21/6836; C09J 2201/606; C09J 2433/00; C09J 2203/326

(57) ABSTRACT

Provided is a pressure-sensitive adhesive sheet capable of maintaining a desired pressure-sensitive adhesive characteristic even in a production method for a semiconductor including, for example, a step of peeling off a support material. The pressure-sensitive adhesive sheet includes a backing layer and a pressure-sensitive adhesive layer, in which the pressure-sensitive adhesive layer has a water contact angle of from 80° to 105°. The pressure-sensitive adhesive sheet is used in a production method for a semiconductor including a step in which the pressure-sensitive adhesive layer is brought into contact with a solvent having a solubility in water at 20° C. of 1 g/100 mL or less.

This application claims priority under 35 U.S.C. Section 119 to Japanese Patent Application No. 2014-248989 filed on Dec. 9, 2014, which are herein incorporated by references.

### BACKGROUND OF THE INVENTION

1. Field of the Invention

The present invention relates to a pressure-sensitive adhesive sheet to be used in production of a semiconductor.

2. Description of the Related Art

A semiconductor wafer is produced in a large-diameter state, and a pattern is formed on its front surface. After that, its back surface is ground (backgrinding) to reduce a thickness of the wafer to generally from about 40 μm to about 600 μm. Subsequently, the ground semiconductor wafer is cut and separated into small element pieces (dicing), and then further subjected to a mounting step. Thus, a desired semiconductor element is obtained. In the production process for the semiconductor, a pressure-sensitive adhesive sheet is used for fixing the semiconductor wafer or a dicing frame (such as an SUS ring) to be used in the dicing step.

The semiconductor wafer is reduced in strength owing to the reduction in thickness in the backgrinding step, and hence the wafer may be cracked and/or warped. Further, the wafer having the reduced strength is difficult to handle. Accordingly, in some cases, glass, a hard plastic, or the like is bonded as a support material onto the wafer in advance of the backgrinding step, thereby securing the strength of the wafer. The support material is bonded onto the wafer using, for example, an adhesive composition or an adhesive tape. The support material can support the wafer while the wafer is subjected to the backgrinding step, and steps of forming back wiring and bumps. After that, the wafer is bonded onto the pressure-sensitive adhesive sheet (such as a dicing sheet), and is subjected to the dicing step after the support material is peeled off. Accordingly, as an adhesive for bonding the support material, there is a proposal of an adhesive which can be easily peeled off after the backgrinding step (for example, Japanese Patent Application Laid-open No. 2014-37458). In general, when the support material is bonded using the adhesive, the support material is peeled off by dissolving the adhesive using a solvent. However, depending on the kind of the solvent to be used, physical properties of a pressure-sensitive adhesive layer of the pressure-sensitive adhesive sheet may be affected, with the result that the pressure-sensitive adhesive sheet cannot sufficiently hold the wafer and the dicing frame in some cases. Accordingly, there is a proposal of a method involving removing the adhesive while forming a protective coating on a surface of the pressure-sensitive adhesive sheet (for example, Japanese Patent Application Laid-open No. 2013-247299). As described above, there is a demand for a pressure-sensitive adhesive sheet capable of maintaining a desired pressure-sensitive adhesive characteristic even in a production method for a semiconductor including the step of peeling off the support material.

### SUMMARY OF THE INVENTION

The present invention has been made in order to solve the problem of the related art described above, and a primary object of the present invention is to provide a pressure-sensitive adhesive sheet capable of maintaining a desired pressure-sensitive adhesive characteristic even in a production method for a semiconductor including, for example, a step of peeling off a support material.

According to one embodiment of the present invention, there is provided a pressure-sensitive adhesive sheet, including a backing layer and a pressure-sensitive adhesive layer, in which the pressure-sensitive adhesive layer has a water contact angle of from 80° to 105°. The pressure-sensitive adhesive sheet is used in a production method for a semiconductor including a step in which the pressure-sensitive adhesive layer is brought into contact with a solvent having a solubility in water at 20° C. of 1 g/100 mL or less.

In one embodiment, the solvent is at least one kind selected from the group consisting of a terpene-based solvent, an aromatic hydrocarbon-based solvent, a cycloalkane, an alkene, an alkane, and an acetic acid ester.

In one embodiment, the solvent is at least one kind selected from the group consisting of p-menthane, limonene, mesitylene, cyclohexane, methylcyclohexane, 1-dodecene, isododecane, and butyl acetate.

In one embodiment, a composition for forming the pressure-sensitive adhesive layer contains a hydrophilic monomer.

In one embodiment, the hydrophilic monomer is a hydroxyl group-containing monomer and/or an (N-substituted) amide-based monomer.

According to another embodiment of the present invention, there is provided a dicing sheet. The dicing sheet includes the pressure-sensitive adhesive sheet.

In a production method for a semiconductor involving using a support material, the solvent having a solubility in water at 20° C. of 1 g/100 mL or less may be used in order to dissolve and remove an adhesive used in the bonding of the support material. The pressure-sensitive adhesive sheet according to the embodiment of the present invention includes the backing layer and the pressure-sensitive adhesive layer having a water contact angle of from 80° to 105°. With such construction, even when the pressure-sensitive adhesive sheet is used in the production method for a semiconductor including the step in which the pressure-sensitive adhesive layer of the pressure-sensitive adhesive sheet is brought into contact with the solvent having a solubility in water at 20° C. of 1 g/100 mL or less, the pressure-sensitive adhesive sheet can maintain a desired pressure-sensitive adhesive characteristic. Accordingly, even when the production method includes such step, a wafer and a dicing frame can be appropriately held. In addition, the use of the pressure-sensitive adhesive sheet of the present invention obviates the need to use means and a step for protecting the pressure-sensitive adhesive layer from the solvent to be used in the step of peeling off the support material. Accordingly, the production efficiency of the semiconductor can be improved.

### BRIEF DESCRIPTION OF THE DRAWINGS

FIG. 1 is a schematic cross-sectional view of a pressure-sensitive adhesive sheet according to one embodiment of the present invention.

### DETAILED DESCRIPTION OF THE PREFERRED EMBODIMENTS

Now, embodiments of the present invention are described, but the present invention is not limited to these embodiments.

A. Pressure-sensitive Adhesive Sheet

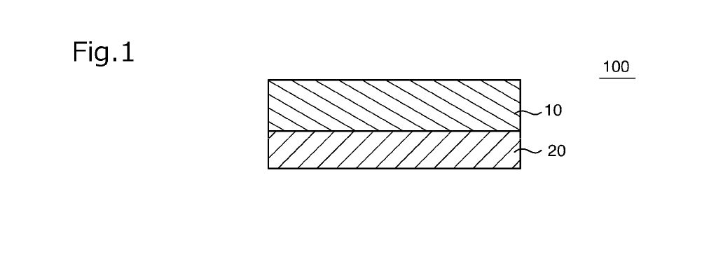

FIG. 1 is a schematic cross-sectional view of a pressure-sensitive adhesive sheet according to one embodiment of the present invention. A pressure-sensitive adhesive sheet 100 of the present invention includes a pressure-sensitive adhesive layer 10 and a backing layer 20. The pressure-sensitive adhesive layer 10 has a water contact angle of from 80° to 150°. When the pressure-sensitive adhesive layer has such characteristic, even in the case where the pressure-sensitive adhesive layer is brought into contact with a solvent having a solubility in water at 20° C. of 1 g/100 mL or less, the pressure-sensitive adhesive layer can maintain its pressure-sensitive adhesive characteristic. In one embodiment, the pressure-sensitive adhesive sheet 100 may further include a separator (not shown) on the surface of the pressure-sensitive adhesive layer 10 which is not brought into contact with the backing layer 20. The pressure-sensitive adhesive sheet of the present invention may further include any appropriate other layer. An example of the other layer is a surface layer which is arranged on the opposite side of the backing layer to the pressure-sensitive adhesive layer and is capable of imparting heat resistance to the pressure-sensitive adhesive sheet.

The pressure-sensitive adhesive layer 10 of the pressure-sensitive adhesive sheet of the present invention has a water contact angle of from 80° to 105°, preferably from 83° to 102°. When the water contact angle of the pressure-sensitive adhesive layer falls within the above-mentioned range, even in the case where the pressure-sensitive adhesive layer is brought into contact with a solvent having a solubility in water at 20° C. of 1 g/100 mL or less, the pressure-sensitive adhesive layer can maintain its characteristics. The water contact angle of the pressure-sensitive adhesive layer may be measured by dropping distilled water onto the surface of the pressure-sensitive adhesive layer at 25° C. on the basis of a sessile drop method through the use of a contact angle meter.

The thickness of the pressure-sensitive adhesive sheet 100 may be set to any appropriate value. The thickness of the pressure-sensitive adhesive sheet 100 is preferably from 50 μm to 350 μm, more preferably from 70 μm to 200 μm.

In one embodiment, the pressure-sensitive adhesive sheet of the present invention may be suitably used as a pressure-sensitive adhesive sheet for a dicing step (dicing sheet).

A-1. Backing Layer

The backing layer 20 may be formed of any appropriate resin. Examples of the resin used in the formation of the backing include polyester-based resins, such as polyethylene terephthalate, polyethylene naphthalate, polybutylene terephthalate, and polybutylene naphthalate, polyolefin-based resins, such as low-density polyethylene, linear polyethylene, medium-density polyethylene, high-density polyethylene, ultralow-density polyethylene, random copolymer polypropylene, block copolymer polypropylene, homopolypropylene, polybutene, polymethylpentene, and an ethylene-propylene copolymer, an ethylene-vinyl acetate copolymer, an ionomer resin, an ethylene-(meth)acrylic acid copolymer, an ethylene-(meth)acrylate (random, alternating) copolymer, an ethylene-butene copolymer, an ethylene-hexene copolymer, a polyurethane-based resin, polyetherketone, polyvinyl alcohol, polyvinylidene chloride, polyvinyl chloride, a vinyl chloride-vinyl acetate copolymer, polyvinyl acetate, a polyamide-based resin, a polyimide-based resin, a cellulose-based resin, a fluorine-based resin, a silicone resin, a polyether-based resin, a styrene-based resin, such as polystyrene, a polycarbonate-based resin, and a polyether sulfone-based resin, and cross-linked bodies thereof.

The above-mentioned backing layer may further contain any other component as long as the effects of the present invention are not impaired. Examples of the other component include a cross-linking agent, a photopolymerization initiator, a catalyst, an antioxidant, a UV absorber, a light stabilizer, a heat stabilizer, and an antistatic agent. The kind and usage amount of the other component may be appropriately selected depending on purposes.

The thickness of the backing layer may be set to any appropriate value. The thickness of the backing layer 20 is preferably from 10 μm to 300 μm, more preferably from 30 μm to 200 μm.

The backing layer 20 may be produced by any appropriate method. The backing layer 20 may be produced by a method such as calender film formation, casting film formation, inflation extrusion, or T-die extrusion. In addition, the production may involve stretching treatment as required.

The backing layer may be subjected to any appropriate surface treatment depending on purposes. Examples of the surface treatment include chromic acid treatment, exposure to ozone, exposure to a flame, exposure to a high-voltage electric shock, ionizing radiation treatment, mat treatment, corona discharge treatment, primer treatment, and cross-linking treatment.

A-2. Pressure-Sensitive Adhesive Layer

The pressure-sensitive adhesive layer 10 of the pressure-sensitive adhesive sheet of the present invention has a water contact angle of from 80° to 105°. The pressure-sensitive adhesive layer may be formed through the use of any appropriate composition for forming the pressure-sensitive adhesive layer (hereinafter referred to as “composition for pressure-sensitive adhesive layer formation”) so that the water contact angle falls within the above-mentioned range. The composition for pressure-sensitive adhesive layer formation preferably contains a hydrophilic monomer. The water contact angle of the pressure-sensitive adhesive layer maybe adjusted to a desired angle by, for example, adjusting the composition of monomers contained in the composition for pressure-sensitive adhesive layer formation (ratio between the hydrophilic monomer and a monomer other than the hydrophilic monomer (such as a hydrophobic monomer)).

Any appropriate monomer having a polar group may be used as the hydrophilic monomer contained in the composition for pressure-sensitive adhesive layer formation. Specific examples thereof include: carboxyl group-containing monomers, such as acrylic acid, methacrylic acid, carboxyethyl acrylate, carboxypentyl acrylate, itaconic acid, maleic acid, fumaric acid, and crotonic acid; acid anhydride monomers, such as maleic anhydride and itaconic anhydride; hydroxyl group-containing monomers, such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxymethylcyclohexyl)methyl methacrylate; sulfonate group-containing monomers, such as styrene sulfonate, allyl sulfonate, 2-(meth)acrylamide-2-methylpropane sulfonate, (meth)acrylamide propane sulfonate, sulfopropyl(meth)acrylate, and (meth)acryloyloxy naphthalene sulfonate; phosphate group-containing monomers, such as 2-hydroxyethylacryloyl phosphate; (N-substituted) amide-based monomers, such as (meth)acrylamide, N,N-dimethyl(meth)acrylamide, N-butyl(meth)acrylamide, N-methylol(meth)acrylamide, N-methylol propane(meth)acrylamide, and acryloylmorpholine; aminoalkyl(meth)acrylate-based monomers, such as aminoethyl(meth)acrylate, N,N-dimethylaminoethyl(meth)acrylate, and t-butylaminoethyl(meth)acrylate; alkoxyalkyl(meth)acrylate-based monomers, such as methoxyethyl(meth)acrylate and ethoxyethyl(meth)acrylate; maleimide-based monomers, such as N-cyclohexylmaleimide, N-isopropylmaleimide, N-laurylmaleimide, and N-phenylmaleimide; itaconimide-based monomers, such as N-methyl itaconimide, N-ethyl itaconimide, N-butyl itaconimide, N-octyl itaconimide, N-2-ethylhexyl itaconimide, N-cyclohexyl itaconimide, and N-lauryl itaconimide; succinimide-based monomers, such as N-(meth)acryloyloxymethylene succinimide, N-(meth)acryloyl-6-oxyhexamethylene succinimide, and N-(meth)acryloyl-8-oxyoctamethylene succinimide; vinyl-based monomers, such as vinyl acetate, vinyl propionate, N-vinylpyrrolidone, methylvinylpyrrolidone, vinylpyridine, vinylpiperidone, vinylpyrimidine, vinylpiperazine, vinylpyrazine, vinylpyrrol, vinylimidazole, vinyloxazole, vinylmorpholine, N-vinylcarboxylic acid amides, styrene, α-methylstyrene, and N-vinyl caprolactam; cyanoacrylate monomers, such as acrylonitrile and methacrylonitrile; epoxy group-containing acrylic monomers, such as glycidyl(meth)acrylate; glycol-based acrylate monomers, such as polyethylene glycol(meth)acrylate, polypropylene glycol(meth)acrylate, methoxyethylene glycol(meth)acrylate, and methoxypolypropylene glycol(meth)acrylate; acrylate-based monomers each having a heterocycle, a halogen atom, or a silicon atom such as tetrahydrofurfuryl(meth)acrylate, fluorine(meth)acrylate, and silicon(meth)acrylate; and polyfunctional monomers, such as hexanediol di(meth)acrylate, (poly)ethylene glycol di(meth)acrylate, (poly)propylene glycol di(meth)acrylate, neopentyl glycol di(meth)acrylate, pentaerythritol di(meth)acrylate, trimethylolpropane tri(meth)acrylate, pentaerythritol tri(meth)acrylate, dipentaerythritol hexa(meth)acrylate, epoxy acrylate, polyester acrylate, and urethane acrylate. A hydroxyl group-containing monomer and/or an (N-substituted) amide-based monomer can be suitably used as the hydrophilic monomer. The hydrophilic monomers may be used alone or in combination.

The hydrophobic monomer contained in the composition for pressure-sensitive adhesive layer formation only needs to be a monomer having a hydrophobic property, and any appropriate monomer can be used. Specific examples thereof include: vinyl alkyl or aryl ethers each having an alkyl or aryl group having 9 to 30 carbon atoms, such as vinyl 2-ethylhexanate, vinyl laurate, vinyl stearate, and stearyl vinyl ether; alkyl esters each having 6 to 30 carbon atoms, such as hexyl(meth)acrylate, heptyl(meth)acrylate, octyl(meth)acrylate, isooctyl acrylate, isononyl acrylate, decyl(meth)acrylate, isodecyl(meth)acrylate, dodecyl(meth)acrylate, 2-ethylhexyl(meth)acrylate, benzyl(meth)acrylate, lauryl(meth)acrylate, oleyl(meth)acrylate, palmityl(meth)acrylate, and stearyl(meth)acrylate; unsaturated vinyl esters of (meth)acrylic acid derived from an aliphatic acid and a fatty alcohol; a monomer derived from cholesterol; and olefin monomers, such as 1-butene, 2-butene, 1-pentene, 1-hexene, 1-octene, isobutylene, and isoprene. The hydrophobic monomers may be used alone or in combination. It should be noted that the hydrophobic monomer used in the present invention refers to a monomer which has a solubility in 100 g of water of 0.02 g or less.

The composition for pressure-sensitive adhesive layer formation may further contain a monomer component other than the hydrophilic monomer and the hydrophobic monomer. Examples of the other monomer component include alkyl acrylates, such as butyl acrylate and ethyl acrylate. The other monomer components may be used alone or in combination.

The composition for pressure-sensitive adhesive layer formation may further contain an isocyanate-based compound having a radiation-curable functional group in the molecule. Examples of the isocyanate-based compound include methacryloyl isocyanate, 2-methacryloyloxyethyl isocyanate, 2-acryloyloxyethyl isocyanate, and m-isopropenyl-α,α-dimethylbenzyl isocyanate.

A commercially available compound may be used as the isocyanate-based compound. Specific examples thereof include a product available under the trade name “DURANATE TPA-100” from Asahi Kasei Chemicals Corporation, and products available under the trade names “CORONATE L”, “CORONATE HL”, “CORONATE HK”, “CORONATE HX”, and “CORONATE 2096” from Nippon Polyurethane Industry Co., Ltd.

In one embodiment, the pressure-sensitive adhesive sheet of the present invention may be used as a pressure-sensitive adhesive sheet for fixing a wafer and a dicing frame in a dicing step (so-called dicing sheet). In this embodiment, the composition for pressure-sensitive adhesive layer formation preferably further contains a photopolymerization initiator. When the pressure-sensitive adhesive layer further contains the photopolymerization initiator, its pressure-sensitive adhesive strength can be reduced by curing the pressure-sensitive adhesive layer through irradiation with UV light. Accordingly, the wafer can be easily peeled from the pressure-sensitive adhesive sheet in the dicing step.

Any appropriate initiator may be used as the photopolymerization initiator. Examples of the photopolymerization initiator include: α-ketol-based compounds, such as 4-(2-hydroxyethoxy)phenyl (2-hydroxy-2-propyl)ketone, α-hydroxy-α,α′-dimethylacetophenone, 2-methyl-2-hydroxypropiophenone, and 1-hydroxycyclohexyl phenyl ketone; acetophenone-based compounds, such as methoxyacetophenone, 2,2-dimethoxy-2-phenylacetophenone, 2,2-diethoxyacetophenone, and 2-methyl-1-[4-(methylthio)-phenyl]-2-morpholinopropane-1; benzoin ether-based compounds, such as benzoin ethyl ether, benzoin isopropyl ether, and anisoin methyl ether; ketal-based compounds, such as benzyl dimethyl ketal; aromatic sulfonyl chloride-based compounds, such as 2-naphthalenesulfonyl chloride; photoactive oxime-based compounds, such as 1-phenone-1,1-propanedione-2-(o-ethoxycarbonyl)oxime; benzophenone-based compounds, such as benzophenone, benzoylbenzoic acid, and 3,3′-dimethyl-4-methoxybenzophenone; thioxanthone-based compounds, such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketones; acylphosphinoxides; and acylphosphonates. The usage amount of the photopolymerization initiator may be set to any appropriate amount.

A commercially available product may be used as the photopolymerization initiator. Examples thereof include products available under the trade names “IRGACURE 651”, “IRGACURE 184”, “IRGACURE 369”, “IRGACURE 819”, and “IRGACURE 2959” from BASF.

The pressure-sensitive adhesive composition may further contain any appropriate additive. Examples of the additive include tackifiers, anti-aging agents, fillers, coloring agents, antistatic agents, plasticizers, and surfactants. The additives may be used alone or in combination. When two or more kinds of the additives are used, the two or more kinds of the additives may be added one by one, or may be simultaneously added. The usage amount of the additive may be set to any appropriate amount.

The thickness of the pressure-sensitive adhesive layer 10 is preferably from 3 μm to 100 μm, more preferably from 5 μm to 65 μm.

B. Production Method for Pressure-sensitive Adhesive Sheet

The pressure-sensitive adhesive sheet of the present invention may be produced by any appropriate method. For example, the pressure-sensitive adhesive sheet may be produced by applying the composition for pressure-sensitive adhesive layer formation onto the backing layer optionally subjected to surface treatment, followed by drying. In addition, the pressure-sensitive adhesive sheet may be produced by applying the composition for pressure-sensitive adhesive layer formation on another base, followed by drying to form the pressure-sensitive adhesive layer, and transferring the pressure-sensitive adhesive layer onto the backing layer. The production method for the pressure-sensitive adhesive sheet of the present invention may include, as required, a step of further laminating a separator on the surface of the pressure-sensitive adhesive layer which is not bonded onto the backing layer. In addition, when the pressure-sensitive adhesive sheet further includes the separator, the pressure-sensitive adhesive sheet may be produced by applying the composition for pressure-sensitive adhesive layer formation onto the peeling agent-treated surface of the separator, followed by drying, and laminating the backing layer on the formed pressure-sensitive adhesive layer.

The composition for pressure-sensitive adhesive layer formation contains the hydrophilic monomer, a monomer other than the hydrophilic monomer (such as the hydrophobic monomer), a solvent, and, as required, any other component. Any appropriate solvent is used as the solvent to be contained in the composition for pressure-sensitive adhesive layer formation.

Examples of a method of applying the composition for pressure-sensitive adhesive layer formation include: coating methods, such as air doctor coating, blade coating, knife coating, reverse coating, transfer roll coating, gravure roll coating, kiss coating, cast coating, spray coating, slot orifice coating, calender coating, electrocoating, dip coating, and die coating; and printing methods including relief printing methods, such as flexographic printing, intaglio printing methods, such as a direct gravure printing method and an offset gravure printing method, litho printing methods, such as an offset printing method, and stencil printing methods, such as a screen printing method.

Any appropriate drying method (such as air drying, blast drying, or heat drying) can be adopted as a method for the drying after the application of the composition for pressure-sensitive adhesive layer formation. In the case of, for example, the heat drying, a drying temperature is typically from 70° C. to 200° C., and a drying time is typically from 1 minute to 10 minutes.

When the pressure-sensitive adhesive layer formed on another base is transferred onto the backing layer, after the formation of a laminate by bonding the pressure-sensitive adhesive layer and the backing layer, the laminate is preferably left to stand still, for example, under a temperature of from 40° C. to 80° C. for from 12 hours to 80 hours in order to achieve close adhesion between the layers.

C. Production Method for Semiconductor Involving Using Pressure-Sensitive Adhesive Sheet

The pressure-sensitive adhesive sheet of the present invention is used in a step in the production of a semiconductor. In particular, the pressure-sensitive adhesive sheet is suitably used in a production method for a semiconductor including a step in which the pressure-sensitive adhesive layer is brought into contact with a solvent having a solubility in water at 20° C. of 1 g/100 mL or less. In one embodiment, the production method for a semiconductor includes the steps of: bonding a semiconductor wafer and a support material with an adhesive composition, an adhesive sheet, or the like; grinding the opposite surface of the semiconductor wafer to the surface having the support material bonded thereonto (backgrinding step); bonding the pressure-sensitive adhesive sheet of the present invention onto the opposite surface of the semiconductor wafer to the surface having the support material bonded thereonto; peeling the support material from the semiconductor wafer; and dicing the semiconductor wafer into small pieces to provide chips.

As described above, the production method for a semiconductor may include the backgrinding step. The semiconductor wafer after the backgrinding step is reduced in strength, and hence there may arise a problem of the wafer itself, specifically the occurrence of a crack and/or warping, and a problem in its handling. For the purpose of eliminating such problems, a support material, such as glass or a hard plastic, is bonded onto the semiconductor wafer in some cases before the backgrinding step is performed. The support material is bonded onto the semiconductor wafer using, for example, an adhesive composition. After that, a pressure-sensitive adhesive sheet (such as a dicing sheet) for fixing a dicing frame (such as an SUS ring) to be used in the dicing step and the semiconductor wafer is bonded onto the semiconductor wafer, and the support material is peeled from the semiconductor wafer. When the support material is bonded onto the semiconductor wafer using the adhesive composition, the support material is peeled off generally by dissolving the adhesive layer with a solvent. The peeling step is performed under a state in which the semiconductor wafer is bonded onto the pressure-sensitive adhesive sheet as described above, and hence the pressure-sensitive adhesive layer of the pressure-sensitive adhesive sheet is brought into contact with the solvent. In addition, as required, the production method for a semiconductor may further include, after the step of peeling off the support material, a step of cleaning off the adhesive remaining on the surface of the wafer with a solvent capable of dissolving the adhesive. In those steps, depending on the solvent to be used, the characteristics of the pressure-sensitive adhesive layer, particularly the pressure-sensitive adhesive characteristic may be impaired. For example, a solvent having a solubility in water at 20° C. of 1 g/100 mL or less, which is capable of satisfactorily dissolving a generally used adhesive, may impair the pressure-sensitive adhesive characteristic of the pressure-sensitive adhesive. In this case, when the pressure-sensitive adhesive sheet of the present invention, which includes the pressure-sensitive adhesive layer having a water contact angle of from 80° to 105° is used, even in the production method for a semiconductor including the step of peeling off the support material, the pressure-sensitive adhesive layer can maintain a desired pressure-sensitive adhesive characteristic.

Any appropriate method is used as a method of bonding the support material onto the semiconductor wafer. An example thereof is a method involving applying any appropriate adhesive composition onto the semiconductor wafer, and then bonding the support material thereonto, followed by drying. Any appropriate material may be used as the support material. Examples thereof include hard plastics, glass, ceramics, and silicon. Examples of a resin contained in the adhesive composition suitable for bonding the support material include a (meth)acrylic polymer, a polyurethane-based resin, a polyvinyl alcohol-based resin, a polyvinyl butyral-based resin, a polyamide-based resin, a polyester-based resin, an epoxy-based resin, a novolak-based resin, and a polyimide-based resin.

The backgrinding step may be performed by any appropriate method.

The step of bonding the pressure-sensitive adhesive sheet of the present invention onto the semiconductor wafer is performed by any appropriate method. For example, the bonding step may be performed by bonding the surface of the semiconductor wafer onto which the support material is not bonded and the pressure-sensitive adhesive layer of the pressure-sensitive adhesive sheet.

The step of peeling off the support material is performed by any appropriate method. In the production method for a semiconductor in which the pressure-sensitive adhesive sheet of the present invention is used, the support material is peeled off by dissolving the adhesive layer using a solvent having a solubility in water at 20° C. of 1 g/100 mL or less.

As described above, the pressure-sensitive adhesive layer of the pressure-sensitive adhesive sheet of the present invention has a water contact angle of from 80° to 150°. Accordingly, even in the case where the solvent having a solubility in water at 20° C. of 1 g/100 mL or less is used, the pressure-sensitive adhesive layer does not allow a desired pressure-sensitive adhesive characteristic to be impaired, and for example, can satisfactorily hold the semiconductor wafer and the dicing frame in the subsequent dicing step. In addition, there is no need to use means and a step for protecting the pressure-sensitive adhesive layer from the solvent to be used in the step of peeling off the support material. Accordingly, the production efficiency of the semiconductor can be improved.

From the viewpoint of a capability to satisfactorily dissolve the adhesive used in the bonding of the support material, the solvent having a solubility in water at 20° C. of 1 g/100 mL or less is used in the step of peeling off the support material. From the viewpoint of a further improved property of dissolving the adhesive, a solvent having a solubility in water at 20° C. of 0.8 g/100 mL or less is preferred.

Any appropriate solvent having a solubility in water at 20° C. of 1 g/100 mL or less is used in the step of peeling off the support material. Specific examples thereof include 2-ethylhexyl acrylate, diethylene glycol ethoxylate acrylate, methyl acetoacetate, acetophenone, anisaldehyde, aniline, 2-aminothiophenol, amyl cinnamic aldehyde, an alkylbenzene benzyl benzoate, methyl benzoate, anthracene, isoeugenol, isostearyl alcohol, diallyl isophthalate, isopropanolamine, isophorone, γ-undecalactone, undecylenic aldehyde, liquid polybutadiene, N-ethylaniline, ethyl-3,5,5-trimethylhexanoate, 2-ethylhexyloxypropylamine, 2-ethylhexyl glycidyl ether, 6-ethoxy-1,2-dihydro-2,2,4-trimethylquinoline, diethyl ethoxymethylene malonate, β-(3,4-epoxycyclohexyl)ethyltrimethoxysilane, benzoyl chloride, eugenol, 10-oxahexadecanolide, okimelanolure, n-octadecylmercaptan, octanol, octanediol, octylic acid, ethyl caprylate, allyl caproate, 1-geranyl carboxylate, citronellyl formate, 2,4-xylidine, xylenol, 3,5-xylenol, quinoline, guaiacol, guaethol, acetyl triethyl citrate, cuminaldehyde, γ-glycidoxypropylmethyldiethoxysilane, γ-glycidoxypropyltrimethoxysilane, a glycerol diaryl ether, m-cresol, p-chloroacetophenone, o-chloroaniline, 2-ethylhexyl chlorocarbonate, phenyl chlorocarbonate, 2-butoxyethyl chlorocarbonate, benzyl chlorocarbonate, γ-chloropropyltrimethoxysilane, o-chlorobenzaldehyde, p-chlorobenzoylchloride, p-chlorobenzotrichloride, geranyl acetate, citronellyl acetate, dihydroterpinyl acetate, cinnamyl acetate, terpinyl acetate, tricyclodecenyl acetate, butylcyclohexyl acetate, benzyl acetate, linalyl acetate, isoamyl salicylate, methyl salicylate, 2-cyanopyrazine, a dialkyldithiophosphoric acid, a dialkylthiophosphoric acid chloride, di-isopropylbenzene hydroperoxide, N,N-diethylaniline, di-2-ethylhexylamine, diethylene glycol bisallyl carbonate, diethylene glycol monobutyl ether acetate, cyclamen aldehyde, allyl cyclohexyl propionate, 2-(1-cyclohexenyl)cyclohexanone, dichloroethyl ether, dichloroethyl formal, 3,4-dichlorotoluene, o-dichlorobenzene, dicyclohexylamine, dibutylaminopropylamine, N,N-dibutylethanolamine, dibutylmethylenebisthioglycolate, dibenzylamine, ethylene glycol dimethacrylate, tetraethylene glycol dimethacrylate, triethylene glycol dimethacrylate, 1,3-butylene glycol dimethacrylate, N,N-dimethylaniline, 1,3-dimethyl-2-imidazolidinone, dimethylbenzylcarbinol, di(α-methylbenzyl)phenol, octyl bromide, o-bromotoluene, lauryl bromide, thioanisole, thiobenzoic acid, 2-ethylhexyl thioglycolate, thiophenol, a linear alkylbenzene, decyl alcohol, decylaldehyde, tetraisopropoxy titanium, tetrahydronaphthalene, tetrahydrofurfuryl acrylate, tetrahydrolinalool, tetramethylene chlorobromide, terpineol, diallyl terephthalate, n-dodecylmercaptan, t-dodecylmercaptan, triacetin, tri-n-octylamine, triglycol dichloride, triglycol dimercaptan, trichlorobenzene, 2,4,6-tri(dimethylaminomethyl)phenol, tridecyl alcohol, tri-n-butylamine, tri-n-butylphosphine, tributyl phosphate (TBP), 4-(trifluoromethyl)benzaldehyde, 2-(trifluoromethyl)benzoyl chloride, trimethylolpropane trimethacrylate, tri(α-methylbenzyl)phenol, 2,2,4-trimethyl-1,3-pentanediol monoiso(diiso)butyrate, trimethylolpropane triacrylate, tolylene diisocyanate, m-toluidine, o-toluidine, naphthenic acid, o-nitrotoluene, p-nitrotoluene, nitrobenzene, butyl lactate, neopentyl glycol diglycidyl ether, nonalactone, nonalactone nonyl alcohol, nonyl phenol, hydroxy citronellal, 2-hydroxypropyl acrylate, 2-(1-piperazinyl)pyrimidine, a diallyl phthalate monomer, diethyl phthalate (DEP), dibutylphthalate (DBP), dimethyl phthalate (DMP), 1,4-butanediol diacrylate, butylphthalyl butylglycolate, p-t-butyl-α-methylhydrocinnamic aldehyde, phenylacetaldehyde, N-phenyl-γ-aminopropyltrimethoxysilane, β-phenylethyl alcohol, phenylxylylethane, phenyl glycidyl ether, ethyl phenylacetate, phenylphosphonic dichloride, dimethyl phenylphosphonate, 2-phenoxyethanol, phenoxyethyl acrylate, p-phenetidine, dibutyl fumarate (DBF), o-fluorobenzonitrile, benzyl propionate, propylene carbonate, propylene glycol, tert-butyl α-bromoisobutyrate, β-bromoethylbenzene, ethyl α-bromobutyrate, diallyl hexahydrophthalate, hexamethylene diisocyanate, 1,6-hexanediol diacrylate, hexythiazox (dichlorvos (DDVP) 50%), hexylcinnamic aldehyde, 2-heptyl alcohol, veratrole, benzyl alcohol, benzyl ether, benzoin isobutyl ether, benzotrichloride, benzonitrile, 1,5-pentanediol, polybutene, dibutyl maleate (DBM), ethyl malonate, isobutyric anhydride, butyric anhydride, an alkyl methacrylate, 2-ethylhexyl methacrylate, glycidyl methacrylate, diethylaminoethyl methacrylate, cyclohexyl methacrylate, stearyl methacrylate, tetrahydrofurfuryl methacrylate, tridecyl methacrylate, 2-hydroxypropyl methacrylate, benzyl methacrylate, lauryl methacrylate, γ-(methacryloxypropyl)trimethoxysilane, methanesulfonyl chloride, p-methylacetophenone, N-methylaniline, methyl N-methylanthranilate, methylnaphthalene, α-methylnaphthalene, p-methylphenylacetaldehyde, ethyl methyl phenyl glycidate, methyl ionone, methoxybutyl β-mercaptopropionate, octyl β-mercaptopropionate, γ-mercaptopropyltrimethoxysilane, mono(α-methylbenzyl)phenol, α-ionone, butyric acid, isobutyl acrylate, butyl acrylate, acetylacetone, allyl acetoacetate, ethyl acetoacetate, allyl glycidyl ether, allyl methacrylate, aluminum di-n-butoxymonoethyl acetoacetate, ethyl orthoformate, ethyl orthoacetate, ethyl caproate, ethyl formate, xylene, m-xylene, o-xylene, p-xylene, m-xylene hexafluoride, cumene, chloroethyl vinyl ether, allyl chlorocarbonate, isobutyl chlorocarbonate, 2-ethoxyethyl chlorocarbonate, n-propyl chlorocarbonate, sec-butyl chlorocarbonate, o-chlorotoluene, p-chlorotoluene, 2-chloropyridine, chlorobenzene, m-chlorobenzotrifluoride, o-chlorobenzotrifluoride, p-chlorobenzotrifluoride, 2,4,6-collidine, isoamyl acetate, cyclohexyl acetate, diisoamyl ether, diisobutylamine, cyclohexanol, cyclohexene oxide, cyclohexanone, cyclohexanone dimethyl acetal, cyclohexyl acrylate, 1,4-dichlorobutane, m-dichlorobenzene, diketene, dicyclopentadiene, 1,8-cineol, divinylbenzene, di-n-butylamine, dibutyl ether, dipentene, 3,5-dimethyl-1-hexyne-3-ol, butyl bromide, a styrene monomer, n-decane, tetrakis-2-ethylhexoxy titanium, tetra-n-butoxy titanium, teflubenzuron, tralomethrin, triadimefon, triallylamine, triallyl trimellitate, triclopyr, tricyclohexylphosphine, n-tridecane, 2-(trifluoromethyl)benzaldehyde, trimethyl phosphite, 1,4-bis(trifluoromethyl)benzene, N,O-bis(trimethylsilyl)acetamide, methyl α-hydroxyisobutyrate, vinyltriethoxysilane, vinyltrimethoxysilane, vinyltoluene, 2-vinylpyridine, 4-vinylpyridine, methyl pyruvate, phenisobromolate, phenetole, isoamyl propionate, ethyl α-bromoisobutyrate, bromobenzene, n-hexylamine, n-hexyl aldehyde, heavy solvent naphtha, 3-heptylalcohol, benzylethylaniline, benzylmercaptan, benzaldehyde, myclobutanil, mesitylene, ethyl methacrylate, dimethylaminoethyl methacrylate, i-butyl methacrylate, n-butyl methacrylate, t-butyl methacrylate, methyl isobutyl carbinol, methyl ethyl ketoxime, methylcyclohexanol, methylcyclohexanone, α-methylstyrene, a p-methylstyrene monomer, 3-methyl-1-pentyn-3-ol, methoxybutyl acetate, p-menthane, a hydroperoxide, methyl monochloroacetate, mono-sec-butoxy aluminum diisopropylate, butyl iodide, isoamyl butyrate, isopropyl butyrate, ethyl butyrate, butyl butyrate, limonene, 2,4-lutidine, 2,5-lutidine, 2,6-lutidine, 3,4-lutidine, 3,5-lutidine, diisodecyl adipate (DIDA), diisononyl adipate (DINA), dioctyl adipate (DOA), di-2-ethylhexyl azelate (DOZ), N-ethyl toluenesulfonamide (o-, p-mixture), ethylene brassylate, octadecyl isocyanate, octyl diphenyl phosphate (ODP), acetyl tributyl citrate, glycerol diglycidyl ether, glycerol triglycidyl ether, cresyl diphenyl phosphate (CDP), diallyl chlorendate, diglycerine, diphenyl isodecyl phosphite, dibutyl diglycol adipate (BXA), dodecylbenzenesulfonic acid, tricresyl phosphate (TCP), tri(chloroethyl)phosphate (TCEP), tris(2-ethylhexyl)phosphate (TOP), tris(2-chloroethyl)phosphate, tris(β-chloropropyl)phosphate (TCPP), trisdichloropropyl phosphate (CRP), tris(nonylphenyl)phosphite, tris(mono and/or dinonylphenyl)phosphite, triphenyl phosphite, tributoxyethyl phosphate (TBXP), tribenzylphenol, trimethylolpropane tris-(β-thiopropionate), trimethylolpropane polyglycidyl ether, a trimellitic acid-based plasticizer, Neo SK-OIL L-400 (manufactured by Soken Tecnix Co., Ltd., mineral oil-based heat medium), Neo SK-OIL 1400 (manufactured by Soken Tecnix Co., Ltd., synthetic heat medium), rapeseed oil, piperonyl butoxide, piperonyl butoxide (emulsion), phenyldiisodecyl phosphite, diisodecyl phthalate (DIDP), diisononyl phthalate (DINP), dioctyl phthalate (DOP), diheptylphthalate (DHP), butylbenzyl phthalate (BBP), 4,4′-butylidene-bis(3-methyl-6-t-butylphenyl-di-tridecyl)phosphite, pentaerythritol triacrylate, polyethylene glycol diglycidyl ether (n is about 13 or more), polytetramethylene ether glycol (having a molecular weight of less than 1,000), polyhydroxypolyolefin (liquid), polypropylene glycol diglycidyl ether (n is or more), polymethylene polyphenyl polyisocyanate, liquid paraffin, 1-dodecene, isododecane, cyclohexane, methylcyclohexane, and butyl acetate.

The solvent having a solubility in water at 20° C. of 1 g/100 mL or less is preferably at least one kind selected from the group consisting of a terpene-based solvent, an aromatic hydrocarbon-based solvent, a cycloalkane, an alkane, an alkene, and an acetic acid ester. Through the use of any such solvent, the adhesive composition to be used for temporarily fixing the support material onto the silicon wafer can be removed and cleaned off with high efficiency. The solvent having a solubility in water at 20° C. of 1 g/100 mL or less is more preferably at least one kind selected from the group consisting of p-menthane, limonene, mesitylene, cyclohexane, methylcyclohexane, 1-dodecene, isododecane, and butyl acetate. Through the use of any such solvent, the adhesive composition to be used for temporarily fixing the support material onto the silicon wafer can be removed and cleaned off with additionally high efficiency.

The dicing step may be performed by any appropriate method. Typically, the semiconductor wafer is diced into small pieces with any appropriate blade. For example, the semiconductor wafer is diced into small pieces with a round blade rotated at a high speed.

In one embodiment, the pressure-sensitive adhesive layer of the pressure-sensitive adhesive sheet of the present invention may contain a photopolymerization initiator. In this case, the production method for a semiconductor preferably further includes a step of irradiating the pressure-sensitive adhesive sheet with UV light. The pressure-sensitive adhesive layer containing the photopolymerization initiator is cured through a UV light irradiation step, and thus easily peeled. Accordingly, the pressure-sensitive adhesive sheet can be easily peeled from the resultant semiconductor.

### EXAMPLES

Now, the present invention is specifically described by way of Examples, but the present invention is not limited by these Examples.

### Synthesis Example 1

### Preparation of Acrylic UV-Curable Pressure-Sensitive Adhesive Solution 1

100 Parts by weight of 2-methoxyethyl acrylate, 27 parts by weight of acryloylmorpholine, and 22 parts by weight of 2-hydroxyethyl acrylate were mixed to prepare a monomer liquid 1. Subsequently, nitrogen was introduced into a reaction vessel equipped with a nitrogen inlet tube, a thermometer, and a stirrer, and under the nitrogen atmosphere, 500 parts by weight of ethyl acetate, the monomer liquid 1, and 0.2 part by weight of azobisisobutyronitrile (AIBN) were loaded and stirred at 60° C. for 24 hours. After that, the resultant was cooled to room temperature to provide an acrylic copolymer solution containing an acrylic copolymer (weight-average molecular weight: 600,000). To the resultant acrylic copolymer solution, 24 parts by weight of 2-methacryloyloxyethyl isocyanate was added to cause a reaction, to thereby add an NCO group to a terminal OH group in a 2-hydroxyethyl acrylate side chain in the copolymer. Thus, an acrylic copolymer solution 1 having a terminal carbon-carbon double bond and having a weight-average molecular weight of 800,000 was obtained.

To the resultant acrylic copolymer solution 1, 3 parts by weight of a photopolymerization initiator (trade name: “IRGACURE 651”, manufactured by Ciba Specialty Chemicals) and 1 part by weight of a polyisocyanate compound (trade name: “CORONATE L”, manufactured by Nippon Polyurethane Industry Co., Ltd.) were added to provide an acrylic UV-curable pressure-sensitive adhesive solution 1.

### Synthesis Example 2

### Preparation of Acrylic UV-Curable Pressure-Sensitive Adhesive Solution 2

100 Parts by weight of butyl acrylate, 78 parts by weight of ethyl acrylate, and 40 parts by weight of 2-hydroxyethyl acrylate were mixed to prepare a monomer liquid 2. Subsequently, nitrogen was introduced into a reaction vessel equipped with a nitrogen inlet tube, a thermometer, and a stirrer, and under the nitrogen atmosphere, 218 parts by weight of toluene, the monomer liquid 2, and 0.3 part by weight of AIBN were loaded and stirred at 60° C. for 24 hours. After that, the resultant was cooled to room temperature to provide an acrylic copolymer solution containing an acrylic copolymer (weight-average molecular weight: 500,000). To the resultant acrylic copolymer solution, 43 parts by weight of 2-methacryloyloxyethyl isocyanate was added to cause a reaction, to thereby add an NCO group to a terminal OH group in a 2-hydroxyethyl acrylate side chain in the copolymer. Thus, an acrylic copolymer solution 2 having a terminal carbon-carbon double bond and having a weight-average molecular weight of 500,000 was obtained.

To the resultant acrylic copolymer solution 2, 3 parts by weight of a photopolymerization initiator (trade name: “IRGACURE 651”, manufactured by Ciba Specialty Chemicals) and 1 part by weight of a polyisocyanate compound (trade name: “CORONATE L”, manufactured by Nippon Polyurethane Industry Co., Ltd.) were added to provide an acrylic UV-curable pressure-sensitive adhesive solution 2.

### Synthesis Example 3

### Preparation of Acrylic Pressure-Sensitive Adhesive Solution 3

30 Parts by weight of 2-ethylhexyl acrylate, 70 parts by weight of ethyl acrylate, 5 parts by weight of methyl methacrylate, and 4 parts by weight of 2-hydroxyethyl acrylate were mixed to prepare a monomer liquid 3. Subsequently, nitrogen was introduced into a reaction vessel equipped with a nitrogen inlet tube, a thermometer, and a stirrer, and under the nitrogen atmosphere, 110 parts by weight of toluene, the monomer liquid 3, and 0.2 part by weight of AIBN were loaded and stirred at 60° C. for 24 hours. After that, the resultant was cooled to room temperature to provide an acrylic copolymer solution 3 containing an acrylic copolymer (weight-average molecular weight: 500,000).

To the resultant acrylic copolymer solution 3, 1 part by weight of a polyisocyanate compound (trade name: “CORONATE L”, manufactured by Nippon Polyurethane Industry Co., Ltd.) was added to provide an acrylic pressure-sensitive adhesive solution 3.

### Synthesis Example 4

### Preparation of Acrylic UV-Curable Pressure-Sensitive Adhesive Solution 4

130 Parts by weight of 2-methoxyethyl acrylate and 22 parts by weight of 2-hydroxyethyl acrylate were mixed to prepare a monomer liquid 4. Subsequently, nitrogen was introduced into a reaction vessel equipped with a nitrogen inlet tube, a thermometer, and a stirrer, and under the nitrogen atmosphere, 500 parts by weight of ethyl acetate, the monomer liquid 4, and 0.2 g of AIBN were loaded and stirred at 60° C. for 24 hours. After that, the resultant was cooled to room temperature to provide an acrylic copolymer solution containing an acrylic copolymer (weight-average molecular weight: 800,000). To the resultant acrylic copolymer solution, 24 parts by weight of 2-methacryloyloxyethyl isocyanate was added to cause a reaction, to thereby add an NCO group to a terminal OH group in a 2-hydroxyethyl acrylate side chain in the copolymer. Thus, an acrylic copolymer solution 4 having a terminal carbon-carbon double bond and having a weight-average molecular weight of 800,000 was obtained.

To the resultant acrylic copolymer solution 4, 3 parts by weight of a photopolymerization initiator (trade name: “IRGACURE 651”, manufactured by Ciba Specialty Chemicals) and 1 part by weight of a polyisocyanate compound (trade name: “CORONATE L”, manufactured by Nippon Polyurethane Industry Co., Ltd.) were added to provide an acrylic UV-curable pressure-sensitive adhesive solution 4.

### Synthesis Example 5

### Preparation of Acrylic Pressure-sensitive Adhesive Solution 5

75 Parts by weight of 2-ethylhexyl acrylate, 25 parts by weight of acryloylmorpholine, 3 parts by weight of acrylic acid, and 0.1 part by weight of 2-hydroxyethyl acrylate were mixed to prepare a monomer liquid 5. Subsequently, nitrogen was introduced into a reaction vessel equipped with a nitrogen inlet tube, a thermometer, and a stirrer, and under the nitrogen atmosphere, 103 parts by weight of ethyl acetate, the monomer liquid 5, and 0.2 g of AIBN were loaded and stirred at 60° C. for 24 hours. After that, the resultant was cooled to room temperature to provide an acrylic copolymer solution 5 containing an acrylic copolymer (weight-average molecular weight: 1,000,000).

To the resultant acrylic copolymer solution 5, 1 part by weight of a polyisocyanate compound (trade name: “CORONATE L”, manufactured by Nippon Polyurethane Industry Co., Ltd.) was added to provide an acrylic pressure-sensitive adhesive solution 5.

### Example 1

The acrylic UV-curable pressure-sensitive adhesive solution 1 obtained in Synthesis Example 1 was applied so as to have a thickness after drying of 10 μm onto the peeling agent-treated surface of a separator (trade name: “Cerapeel”, manufactured by Toray Advanced Film Co., Ltd.), and was cross-linked by heating at 120° C. for 2 minutes to form a UV-curable pressure-sensitive adhesive layer. Subsequently, one surface of a backing (thickness: 70 μm, film formed of linear low-density polyethylene) was subjected to corona treatment, and the surface of the resultant UV-curable pressure-sensitive adhesive layer and the surface of the backing subjected to the corona treatment were bonded to provide a pressure-sensitive adhesive sheet 1.

### Example 2

A pressure-sensitive adhesive sheet 2 was obtained in the same manner as in Example 1 except that the acrylic UV-curable pressure-sensitive adhesive solution 2 obtained in Synthesis Example 2 was used in place of the acrylic UV-curable pressure-sensitive adhesive solution 1.

### Example 3

A pressure-sensitive adhesive sheet 3 was obtained in the same manner as in Example 1 except that the acrylic pressure-sensitive adhesive solution 3 obtained in Synthesis Example 3 was used in place of the acrylic UV-curable pressure-sensitive adhesive solution 1.

### Comparative Example 1

A pressure-sensitive adhesive sheet C1 was obtained in the same manner as in Example 1 except that the acrylic UV-curable pressure-sensitive adhesive solution 4 obtained in Synthesis Example 4 was used in place of the acrylic UV-curable pressure-sensitive adhesive solution 1.

### Comparative Example 2

A pressure-sensitive adhesive sheet C2 was obtained in the same manner as in Example 1 except that the acrylic pressure-sensitive adhesive solution 5 obtained in Synthesis Example 5 was used in place of the acrylic UV-curable pressure-sensitive adhesive solution 1.

[Evaluation]

The resultant pressure-sensitive adhesive sheets were subjected to the following evaluations. The results are shown in Table 1.

### (1) Contact Angle

The separator was peeled from each of the pressure-sensitive adhesive sheets, and a water contact angle was measured by dropping distilled water onto the surface of the pressure-sensitive adhesive layer at 25° C. on the basis of a sessile drop method using a contact angle meter (manufactured by Kyowa Interface Science Co., Ltd., CA-X).

### (2) Peeling Test

The separator was peeled from each of the resultant pressure-sensitive adhesive sheets, and a stainless-steel (SUS) ring (inner diameter: 7.5 cm, outer diameter: 8.4 cm, depth: 2 mm) and a 1-cm square wafer (thickness: 50 μm) were bonded onto the pressure-sensitive adhesive layer of the pressure-sensitive adhesive sheet so that the wafer was positioned inside the SUS ring. Subsequently, 30 ml of a solvent (p-menthane, solubility in water at 20° C.: 0 g/100 mL) was dropped onto the inside of the bonded SUS ring, and was left to stand at room temperature for 30 minutes. After the standing, the presence or absence of peeling of each of the ring and the wafer was visually confirmed.

In addition, similarly, with the use of limonene (solubility in water at 20° C.: 1 g/100 mL) in place of p-menthane, the presence or absence of peeling of each of the ring and the wafer was visually confirmed. The respective results are shown in Table 1.

Further, similarly, with the use of each of mesitylene (solubility in water at 20° C.: 0 g/100 mL), cyclohexane (solubility in water at 20° C.: 0 g/100 mL), methylcyclohexane (solubility in water at 20° C.: 0 g/100 mL), 1-dodecene (solubility in water at 20° C.: 0 g/100 mL), isododecane (solubility in water at 20° C.: 0 g/100mL), and butyl acetate (solubility in water at 20° C.: 0 g/100 mL) in place of p-menthane, the presence or absence of peeling of each of the ring and the wafer was visually confirmed.

TABLE 1

| | | Presence or absence of peeling after | | | |
|---|---|---|---|---|---|
| | | contact with solvent | | | |
| | | p-Menthane | | Limonene | |
| | Contact | Wafer | Ring | Wafer | Ring |
| | angle (°) | peeling | peeling | peeling | peeling |
| Example 1 | 85 | Absent | Absent | Absent | Absent |
| Example 2 | 99 | Absent | Absent | Absent | Absent |
| Example 3 | 105 | Absent | Absent | Absent | Absent |
| Comparative | 70 | —* | —* | —* | —* |
| Example 1 | | | | | |
| Comparative | 107 | Present | Present | Present | Present |
| Example 2 | | | | | |

*Unevaluable

In the evaluation of each of the pressure-sensitive adhesive sheets obtained in Examples 1 to 3, the ring and the wafer were held by the pressure-sensitive adhesive layer even after contact with the solvent, and no peeling was observed. Also in the case of using any of the solvents other than p-menthane and limonene, as in the cases of p-menthane and limonene, the ring and the wafer were held by the pressure-sensitive adhesive layer, and no peeling was observed. On the other hand, in the evaluation of the pressure-sensitive adhesive sheet C1 obtained in Comparative Example 1, the pressure-sensitive adhesive layer had strong hydrophilicity (that is, had a small contact angle), and hence absorbed moisture in the air, with the result that the pressure-sensitive adhesive did not function, and the ring and the wafer were not able to be bonded onto the pressure-sensitive adhesive sheet. Accordingly, the evaluation itself for the presence or absence of peeling after contact with the solvent was not able to be performed. In addition, in the evaluation of the pressure-sensitive adhesive sheet C2 obtained in Comparative Example 2, in the case of using any of the solvents, peeling of each of the wafer and the ring occurred. The pressure-sensitive adhesive layer of the pressure-sensitive adhesive sheet C2 absorbed the solvent when brought into contact with the solvent. As a result, not only the pressure-sensitive adhesive layer but also the backing layer was swollen, and deformation of the pressure-sensitive adhesive sheet occurred. The peeling occurred probably because of a reduction in pressure-sensitive adhesive strength due to the deformation of the pressure-sensitive adhesive sheet and the absorption of the solvent.

The pressure-sensitive adhesive sheet of the present invention may be suitably used for, for example, temporarily fixing and protecting a workpiece in the production of a semiconductor device (such as a semiconductor wafer).

What is claimed is:

1. A pressure-sensitive adhesive sheet, comprising:
a backing layer; and
a pressure-sensitive adhesive layer,
wherein the pressure-sensitive adhesive layer has a water contact angle of from 80° to 105°, and
wherein the pressure-sensitive adhesive sheet is used in a production method for a semiconductor including a step in which the pressure-sensitive adhesive layer is brought into contact with a solvent having a solubility in water at 20° C. of 1 g/100 mL or less.

2. The pressure-sensitive adhesive sheet according to claim 1, wherein the solvent comprises at least one kind selected from the group consisting of a terpene-based solvent, an aromatic hydrocarbon-based solvent, a cycloalkane, an alkene, an alkane, and an acetic acid ester.

3. The pressure-sensitive adhesive sheet according to claim 1, wherein the solvent comprises at least one kind selected from the group consisting of p-menthane, limonene, mesitylene, cyclohexane, methylcyclohexane, 1-dodecene, isododecane, and butyl acetate.

4. The pressure-sensitive adhesive sheet according to claim 1, wherein a composition for forming the pressure-sensitive adhesive layer contains a hydrophilic monomer.

5. The pressure-sensitive adhesive sheet according to claim 4, wherein the hydrophilic monomer comprises at least one of a hydroxyl group-containing monomer or an (N-substituted) amide-based monomer.

6. A dicing sheet, comprising the pressure-sensitive adhesive sheet of claim 1.
